(19) United States
(12) Patent Application Publication
(10) Pub. No.: US 2024/0061478 A1
(43) Pub. Date: Feb. 22, 2024

(54) CASE AND RESTRICTION MECHANISM THEREOF

(71) Applicant: Wistron Corp., New Taipei City (TW)

(72) Inventor: Jun Hao WANG, New Taipei City (TW)

(21) Appl. No.: 18/069,167

(22) Filed: Dec. 20, 2022

(30) Foreign Application Priority Data
Aug. 19, 2022 (CN) 202211002671.2

(51) Int. Cl. G06F 1/18; G11B 33/02; H05K 5/02

(52) U.S. Cl. CPC G06F 1/181; G11B 33/027; H05K 5/0221

(57) ABSTRACT

A case is provided. The case includes a housing, a cover and a restriction unit. The cover pivots on the housing, wherein the cover is adapted to be rotated relative to the housing. The restriction unit is connected to the cover and moveably connected to the housing, wherein the restriction unit is adapted to restrict the orientation of the cover. The user can thus easily maintain the electronic elements inside the case.

### CROSS REFERENCE TO RELATED APPLICATIONS

This application claims priority of China Patent Application No. 202211002671.2, filed on Aug. 19, 2022, the entirety of which is incorporated by reference herein.

### BACKGROUND OF THE INVENTION

### Field of the Invention

The present invention relates to a case, and in particular to a case and a restriction mechanism of an electronic device.

### Description of the Related Art

The case of a conventional electronic device (such as a server or desktop computer) includes a housing, a front cover, and a lateral cover. The front cover and the lateral cover are affixed to the housing by bolts or hooks. When the user wants to maintain or replace the electronic elements (for example, hard disks or display modules) inside the case, the front cover and the lateral cover must be removed first. It is inconvenient to the user.

### BRIEF SUMMARY OF THE INVENTION

Embodiments of the invention are provided to address the aforementioned difficulty.

In one embodiment, a case is provided. The case includes a housing, a cover and a restriction unit. The cover pivots on the housing, wherein the cover selectively rotates relatively to the housing. The restriction unit is connected to the cover and moveably connected to the housing, wherein an orientation of the cover is restricted by the restriction unit selectively.

In one embodiment, the case further comprises a linkage, wherein the housing has a receiving portion, the cover selectively rotates between a first orientation and a second orientation relatively to the housing, a first end of the linkage pivots on the cover, a second end of the linkage connects to the restriction unit, and the movement of the linkage is restricted by the restriction unit selectively.

In one embodiment, the restriction unit comprises a slider, the slider is connected to the housing, and selectively be moved between a first slider position and a second slider position relatively to the housing, the second end of the linkage pivots on the slider, when the cover is in the first orientation, the slider is in the first slider position, and when the cover is in the second orientation, the slider is in the second slider position.

In one embodiment, the slider comprises a slider wedging portion, the housing comprises a housing wedging portion, when the slider is in the second slider position, the slider wedging portion is wedged against the housing wedging portion.

In one embodiment, the slider comprises an elastic arm, the slider wedging portion is formed on a free end of the elastic arm, the housing wedging portion comprises a slot, when the slider is in the second slider position, the slider wedging portion is wedged against an inner wall of the slot.

In one embodiment, the slider comprises a protrusion, the protrusion is formed on the elastic arm, and the protrusion corresponds to the slot.

In one embodiment, the slider comprises a guiding groove, the housing comprises a guiding post, and the guiding post slides along the guiding groove.

In one embodiment, the cover comprises a cover pivoting portion, the cover pivots on the housing via the cover pivoting portion, and when the cover is in the second orientation, the first end of the linkage, the second end of the linkage and the cover pivoting portion are not collinear.

In one embodiment, the case further comprises a stopper, wherein the stopper is adjustably connected to the housing, the slider comprises a slider wedging portion, and when the slider is in the second slider position, the slider wedging portion is wedged against the stopper.

In one embodiment, the slider comprises an elastic arm, the slider wedging portion is formed on the free end of the elastic arm, the housing comprises a slot, the stopper comprises a stopper wedging portion, and the stopper wedging portion is wedged against the slot.

In one embodiment, the housing comprises a positioning post, the stopper comprises a plurality of elastic wedging portions, and the positioning post is selectively connected with one of the elastic wedging portions.

In one embodiment, the housing comprises a first slot, the second end of the linkage slides along the first slot, when the cover is in the first orientation, the second end of the linkage is in a first position of the first slot, when the cover is in the second orientation, the second end of the linkage is in a second position of the first slot, the second end of the linkage is restricted by the restriction unit selectively, the restriction unit comprises a block and a spring, the spring is connected to the block and the housing, and when the second end of the linkage is in the second position of the first slot, the block restricts the second end of the linkage.

In one embodiment, the housing comprises a second slot, the block slides along the second slot, and an extending direction of the first slot is perpendicular to an extending direction of the second slot.

In one embodiment, the cover further comprises an elastic sheet, the housing comprises a housing buckling portion, when the cover is in the first orientation, the elastic sheet is connected to the housing buckling portion, the elastic sheet comprises an opening portion, the housing buckling portion comprises a buckling protrusion, when the cover is in the first orientation, the opening portion is connected to the buckling protrusion.

In one embodiment, the elastic sheet comprises an inclined surface, the buckling protrusion comprises a curved surface, when the cover is rotated from the second orientation to the first orientation, the inclined surface is pushed by the curved surface, the elastic sheet is deformed, and the inclined surface is moved along the curved surface.

In one embodiment, a restriction mechanism is provided. The restriction mechanism is connected to a housing and a cover. The cover pivoting on the housing. The restriction mechanism comprises a linkage and a restriction unit. The linkage is connected to the cover and the housing. The restriction unit is connected to the linkage, wherein the cover is moved with the linkage for being rotated relatively to the housing, and the restriction unit is moved relatively to the housing via the linkage.

In one embodiment, the restriction unit comprises a slider, the slider is connected to the housing, and the slider selectively moves between a first slider position and a second slider position relatively to the housing, the second end of the linkage pivots on the slider.

In one embodiment, the slider comprises a slider wedging portion, the housing comprises a housing wedging portion, when the slider is in the second slider position, the slider wedging portion is wedged against the housing wedging portion.

In one embodiment, the slider comprises an elastic arm, the slider wedging portion is formed on the free end of the elastic arm, the housing wedging portion comprises a slot, when the slider is in the second slider position, the slider wedging portion is wedged against the inner wall of the slot.

In one embodiment, the restriction mechanism further comprises a stopper, wherein the stopper is adjustably connected to the housing, the slider comprises a slider wedging portion, when the slider is in the second slider position, the slider wedging portion is wedged against the stopper.

Utilizing the case and the restriction mechanism of the embodiment of the invention, the user can easily maintain or replace the electronic elements (for example, hard disks or display modules) after raising the cover. In particular, when the cover is raised, the restriction unit restricts the rotation of the cover. The cover is prevented from unexpected falling when the user replaces the electronic elements, and the operation safety of the user is improved.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A shows an electronic device of an embodiment of the invention, wherein a cover is in the first orientation;

FIG. 1B shows the electronic device of the embodiment of the invention, wherein the cover is in the second orientation;

FIG. 2A is an exploded view of the cover and the housing of a first embodiment of the invention;

FIG. 2B is an assembled view of the cover and the housing of the first embodiment of the invention;

FIGS. 3A and 3B show the movement of the slider of the first embodiment of the invention;

FIGS. 3C and 3D show the relative positions of the slider and the housing of the first embodiment of the invention;

FIG. 4A shows the linkage of the first embodiment of the invention pivoting on the cover;

FIG. 4B shows the supporting effect of the linkage of the first embodiment of the invention;

FIG. 5 shows a stopper of another embodiment of the invention;

FIGS. 6A and 6B show the movement of the stopper of the embodiment of the invention;

FIGS. 7A and 7B show the restriction unit of the second embodiment of the invention;

FIG. 8A shows the elastic sheet of the embodiment of the invention;

FIG. 8B shows a housing buckling portion of the embodiment of the invention;

FIG. 8C shows the elastic sheet of the embodiment of the invention connected to the housing buckling portion; and

FIG. 8D shows the elastic sheet separated from the housing buckling portion of the embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

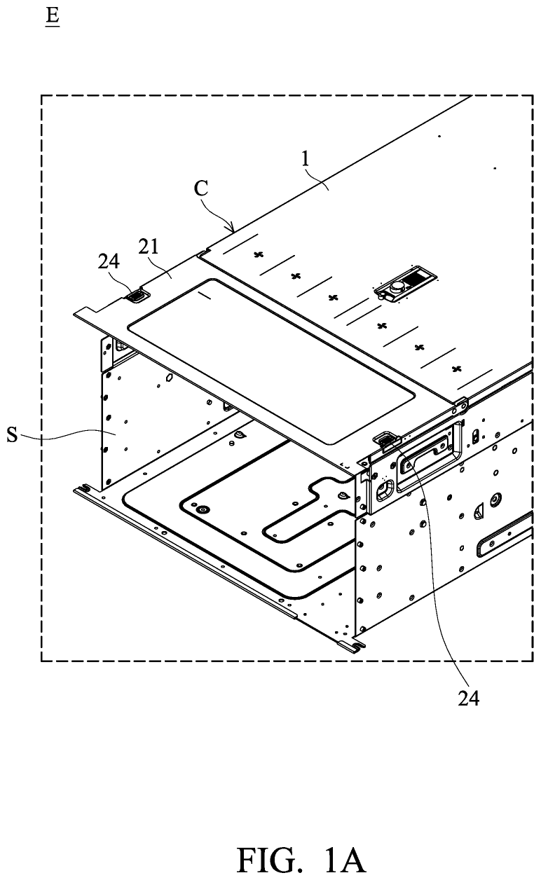

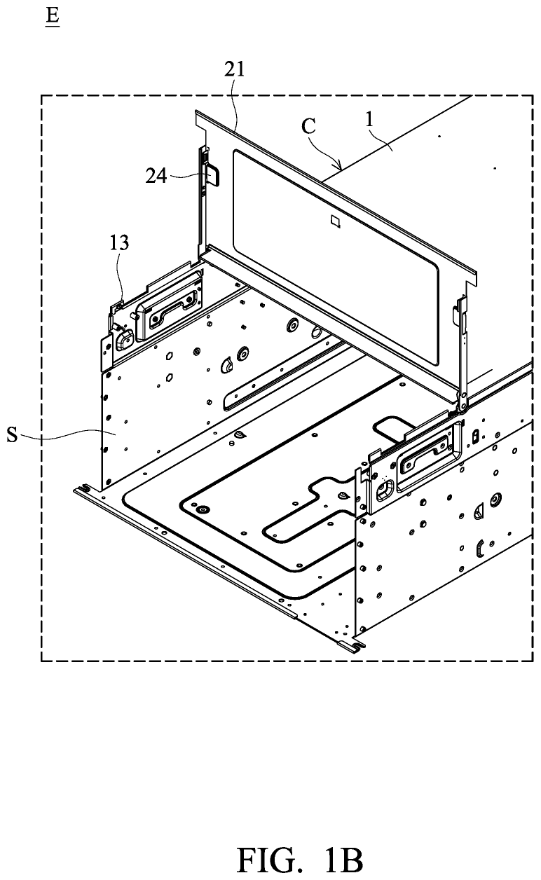

FIG. 1A shows an electronic device of an embodiment of the invention, wherein a cover is in the first orientation. FIG. 1B shows the electronic device of the embodiment of the invention, wherein the cover is in the second orientation. With reference to FIGS. 1A and 1B, the electronic device E of the embodiment of the invention includes a plurality of electronic elements and a case C. In one embodiment, the electronic elements include hard disks (not shown) and display modules (not shown). The hard disks (not shown) and the display modules (not shown) are disposed on a front side of the case, and are covered by the cover. In one embodiment, the display modules (not shown) include a PCIE display module. The case C includes a housing 1, a cover 21 and a restriction unit (not shown). The housing 1 has a receiving portion S. The electronic elements are disposed in the receiving portion S. The cover 21 pivots on the housing 1. The cover 21 is adapted to be rotated between the first orientation (FIG. 1A) and the second orientation (FIG. 1B) relative to the housing 1. The restriction unit (not shown) is connected to the cover 21 and moveably connected to the housing 1. When the cover 21 is in the first orientation (FIG. 1A), the cover 21 covers the receiving portion S. When the cover 21 is in the second orientation (FIG. 1B), the receiving portion S is opened, and the restriction unit is adapted to restrict the rotation of the cover 21.

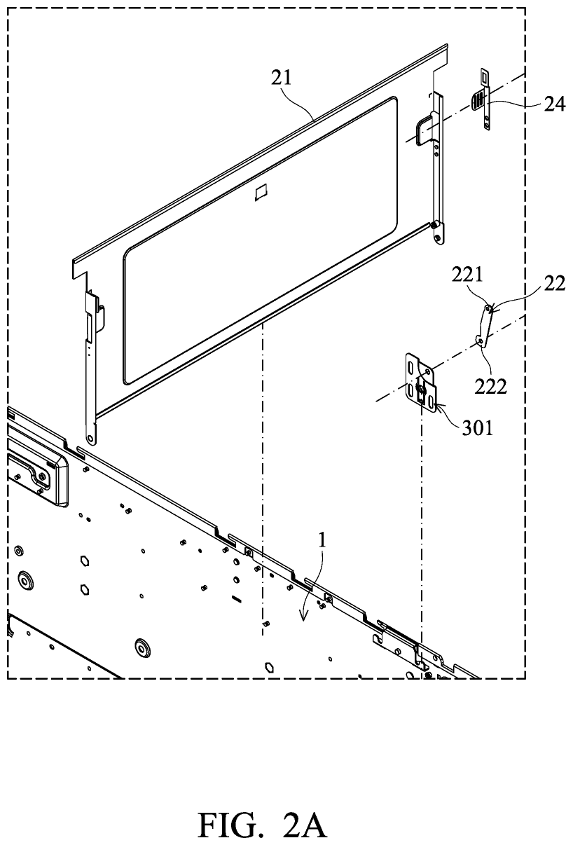

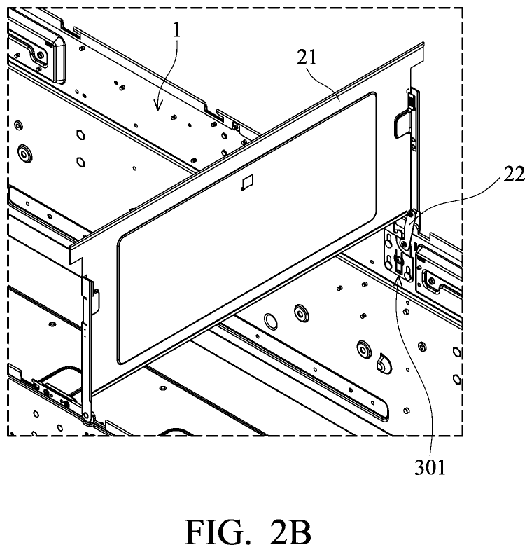

FIG. 2A is an exploded view of the cover and the housing of a first embodiment of the invention. FIG. 2B is an assembled view of the cover and the housing of the first embodiment of the invention. With reference to FIGS. 2A and 2B, in one embodiment, the housing C further comprises a linkage 22. The first end 221 of the linkage 22 pivots on the cover 21. A second end 222 of the linkage 22 is adapted to be connected to the restriction unit 301. When the cover 21 is in the second orientation (FIG. 2B), the restriction unit 301 is adapted to restrict the movement of the linkage 22.

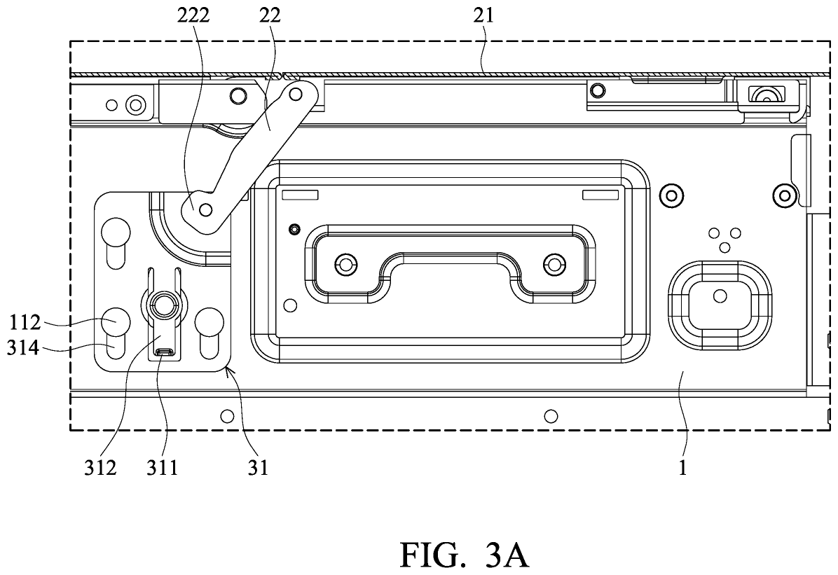

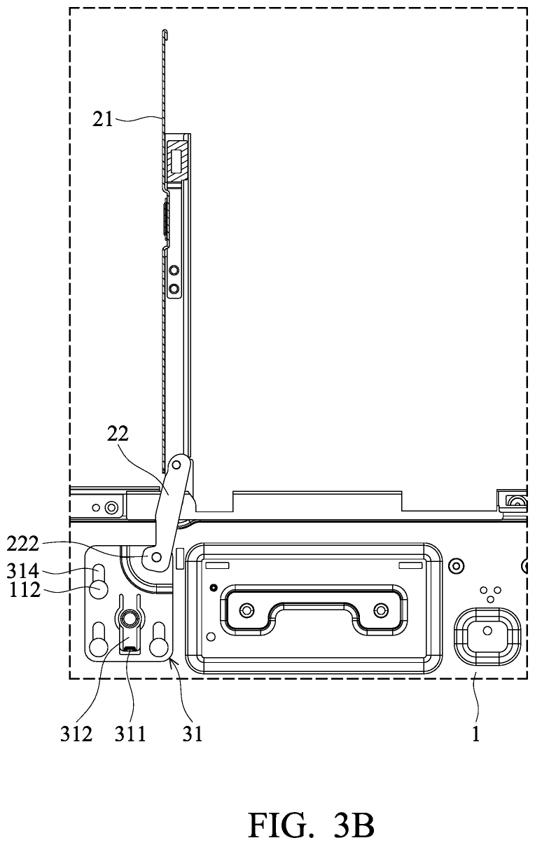

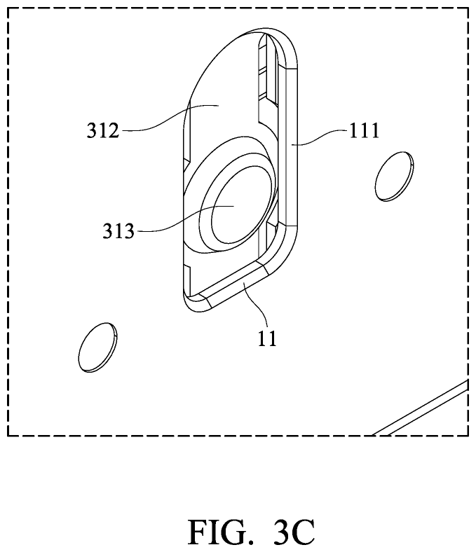

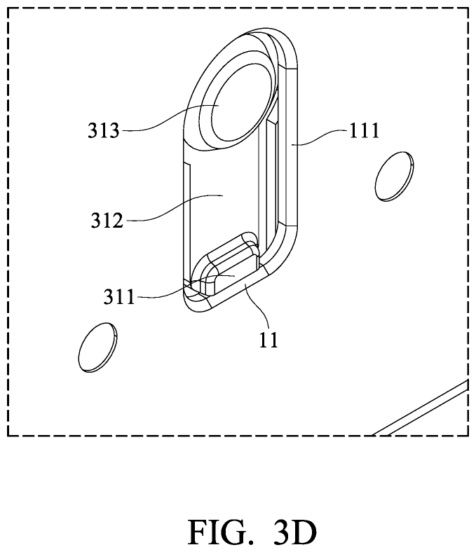

FIGS. 3A and 3B show the movement of the slider of the first embodiment of the invention. With reference to FIGS. 3A and 3B, in one embodiment, the restriction unit comprises a slider 31. The slider 31 is connected to the housing 1, and is adapted to be moved between a first slider position (FIG. 3A) and a second slider position (FIG. 3B) relative to the housing 1. The second end 222 of the linkage 22 pivots on the slider 31. When the cover 21 is in the first orientation (FIG. 3A), the slider 31 is in the first slider position. When the cover 21 is in the second orientation (FIG. 3B), the slider 31 is in the second slider position.

FIGS. 3C and 3D show the relative positions of the slider and the housing of the first embodiment of the invention. With reference to FIGS. 3A, 3B, 3C and 3D, in one embodiment, the slider 31 comprises a slider wedging portion 311. The housing 1 comprises a housing wedging portion 11. When the slider 31 is in the second slider position (FIGS. 3B and 3D), the slider wedging portion 311 is wedged against the housing wedging portion 11.

With reference to FIGS. 3A, 3B, 3C and 3D, in one embodiment, the slider 31 comprises an elastic arm 312. The slider wedging portion 311 is formed on the free end of the elastic arm 312. The housing wedging portion 11 comprises a slot 111. When the slider 31 is in the second slider position (FIGS. 3B and 3D), the slider wedging portion 311 is wedged against the inner wall of the slot 111.

With reference to FIGS. 3A, 3B, 3C and 3D, in one embodiment, the slider 31 comprises a protrusion 313. The protrusion 313 is formed on the elastic arm 312. The protrusion 313 corresponds to the slot 111. The user can separate the slider wedging portion 311 from the housing wedging portion 11 by pressing the protrusion 313.

With reference to FIGS. 3A and 3B, in one embodiment, the slider 31 comprises a plurality of guiding grooves 314. The housing 1 comprises a plurality of guiding posts 112. The guiding posts 112 are adapted to slide along the guiding grooves 314. In this embodiment, the slider 31 is moved in a straight line by the restriction of the guiding posts 112.

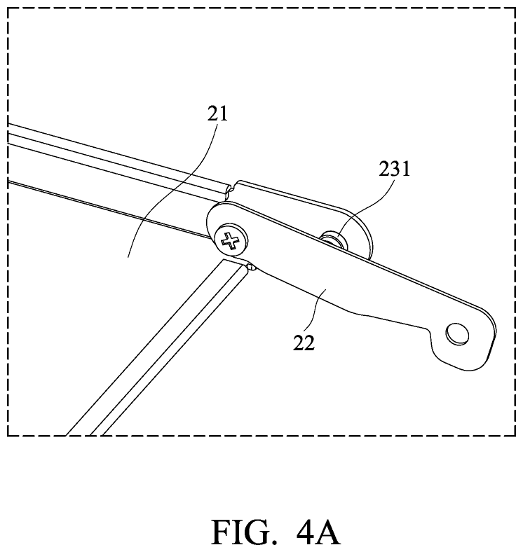

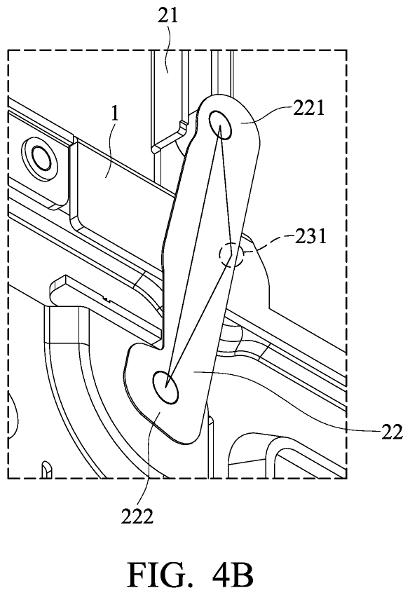

FIG. 4A shows the linkage of the first embodiment of the invention pivoting on the cover. FIG. 4B shows the supporting effect of the linkage of the first embodiment of the invention. With reference to FIGS. 4A and 4B, in one embodiment, the cover 21 comprises two cover pivoting portions 231. The cover 21 pivots on the housing 1 via the cover pivoting portions 231. In one embodiment, the cover pivoting portions 231 can be rivets. When the cover 21 is in the second orientation, the first end 221 of the linkage 22, the second end 222 of the linkage 22 and the cover pivoting portion 231 are not collinear. Therefore, the linkage provides a stable supporting effect.

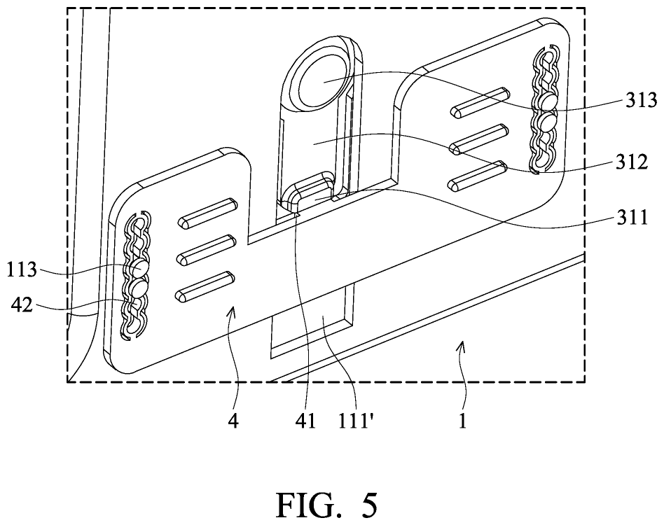

FIG. 5 shows a stopper of another embodiment of the invention. With reference to FIG. 5, in this embodiment, the case further comprises a stopper 4. The stopper 4 is adjustably connected to the housing 1. The slider comprises a slider wedging portion 311. When the slider is in the second slider position, the slider wedging portion 311 is wedged against the stopper 4.

With reference to FIG. 5, in one embodiment, the slider comprises an elastic arm 312. The slider wedging portion 311 is formed on the free end of the elastic arm 312. The housing 1 comprises a slot 111′. The stopper 4 comprises a stopper wedging portion 41. The stopper wedging portion 41 is wedged against the slot 111′. The slider wedging portion 311 is edged against the stopper wedging portion 41.

With reference to FIG. 5, in one embodiment, the slider comprises a protrusion 313. The protrusion 313 is formed on the elastic arm 312. The protrusion 313 corresponds to the slot 111′. The user can separate the slider wedging portion 311 from the stopper wedging portion 41 by pressing the protrusion 313.

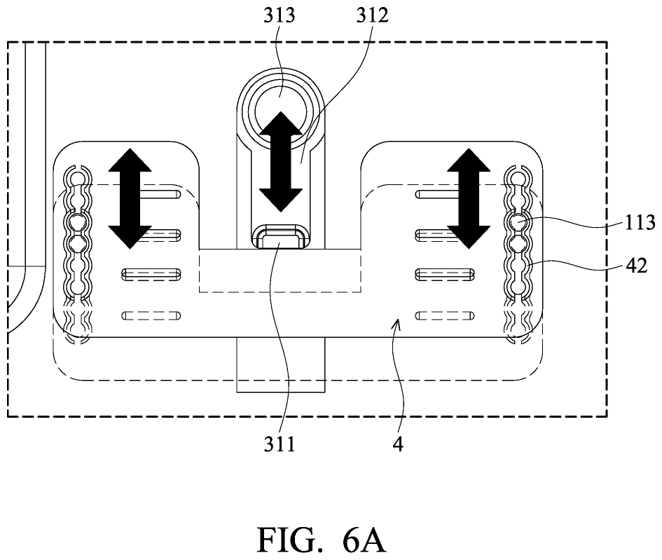

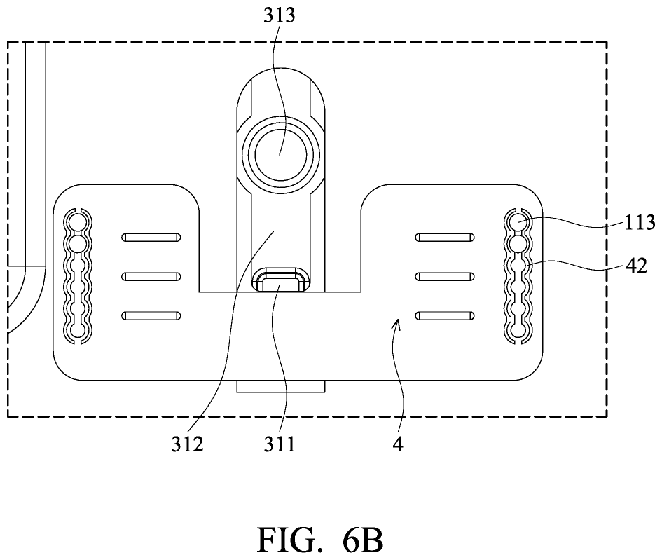

FIGS. 6A and 6B show the movement of the stopper of the embodiment of the invention. With reference to FIGS. 6A and 6B, in one embodiment, the housing 1 comprises at least one positioning post 113. The stopper 4 comprises a plurality of elastic wedging portions 42. The positioning post 113 is selectively combined with one of the elastic wedging portions 42. The position of the slider is modified by adjusting the position of the stopper 4, and the restriction orientation of the cover is changed.

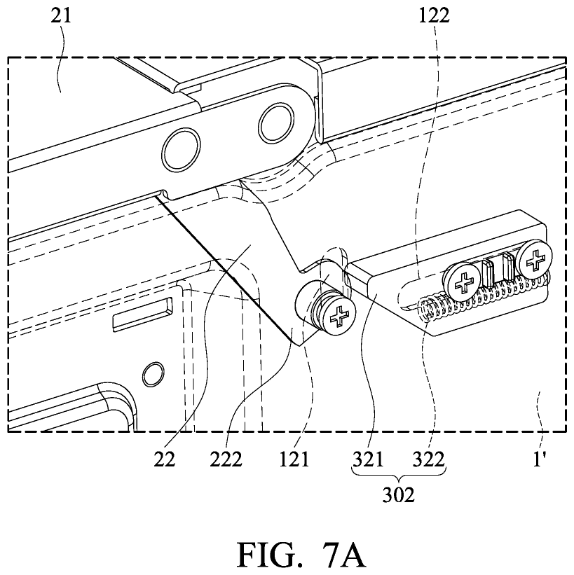

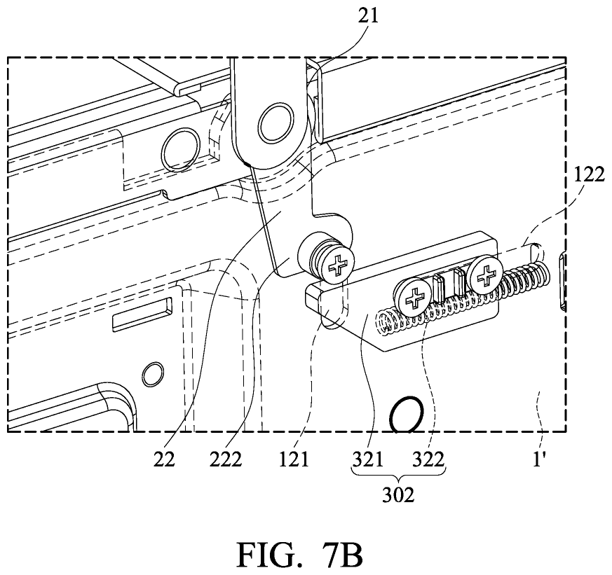

FIGS. 7A and 7B show the restriction unit of the second embodiment of the invention. With reference to FIGS. 7A and 7B, in one embodiment, the housing 1′ comprises a first slot 121. The second end 222 of the linkage 22 slides along the first slot 121. When the cover 21 is in the first orientation, the second end 222 is in the first position (bottom position, FIG. 7A) of the first slot 121. When the cover 21 is in the second orientation, the second end 222 is in the second position (top position, FIG. 7B) of the first slot 121. The restriction unit 302 is adapted to restrict the second end 222.

With reference to FIGS. 7A and 7B, in one embodiment, the restriction unit 302 comprises a block 321 and a spring 322. The spring 322 is connected to the block 321 and the housing 1′. When the second end 222 is in the second position of the first slot 121, the block 321 restrict the second end 222 (FIG. 7B).

With reference to FIGS. 7A and 7B, in one embodiment, the housing 1′ comprises a second slot 122. The block 321 slides along the second slot 122. An extending direction of the first slot 121 is perpendicular to an extending direction of the second slot 122.

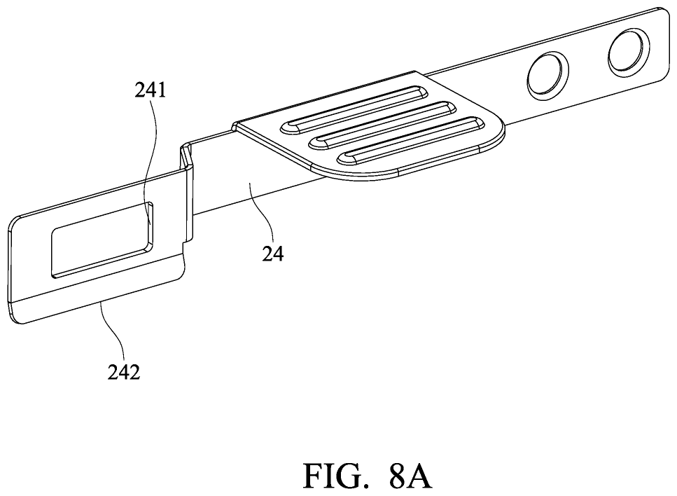

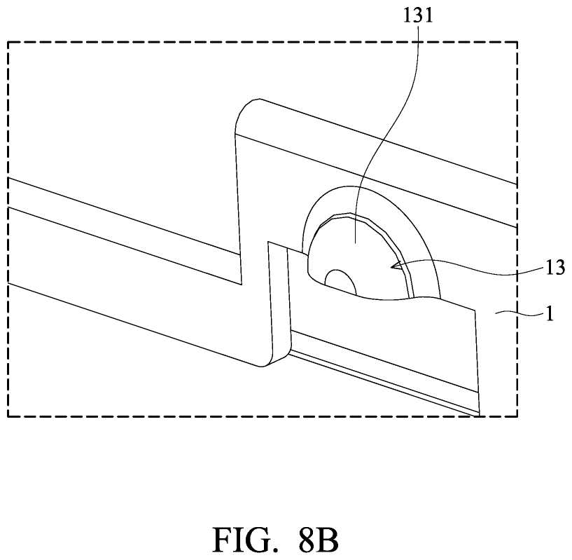

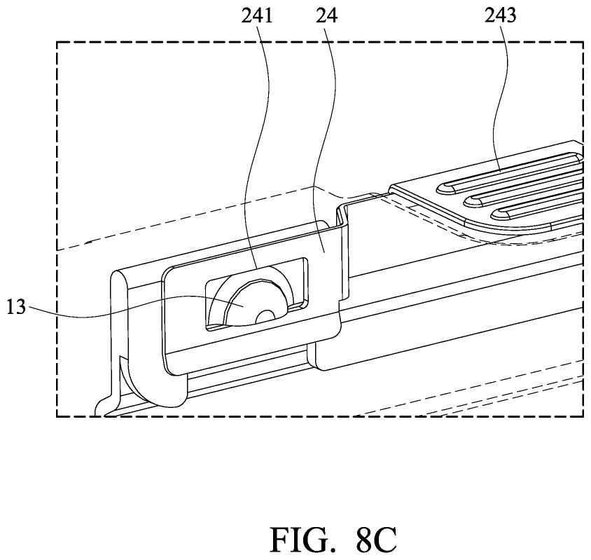

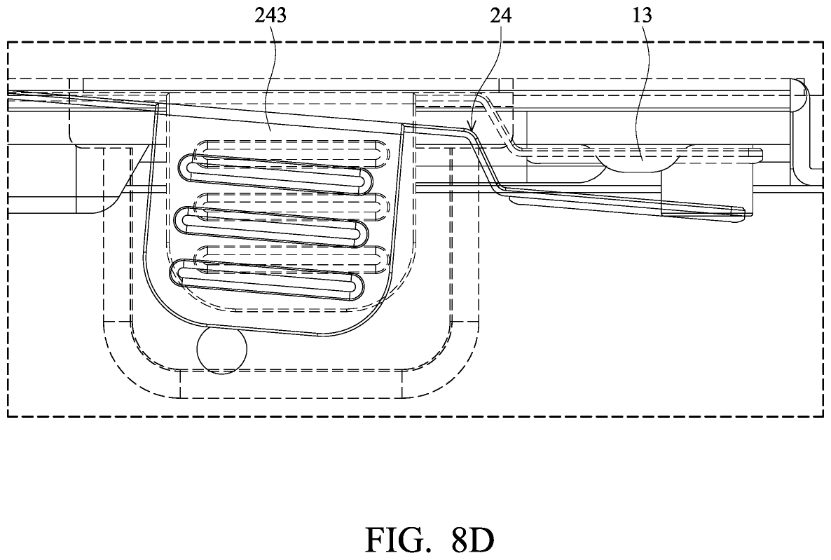

FIG. 8A shows the elastic sheet of the embodiment of the invention. FIG. 8B shows a housing buckling portion of the embodiment of the invention. FIG. 8C shows the elastic sheet of the embodiment of the invention connected to the housing buckling portion. With reference to FIGS. 1A, 1B, 2A, 8A, 8B and 8C, in one embodiment, the cover 21 further comprises an elastic sheet 24. The housing 1 comprises a housing buckling portion 13. When the cover 21 is in the first orientation, the elastic sheet 24 is connected to the housing buckling portion 13, and the cover 21 is thus restricted (FIG. 8C).

With reference to FIGS. 8A, 8B and 8C, in one embodiment, the elastic sheet 24 comprises an opening portion 241. The housing buckling portion 13 comprises a buckling protrusion 13. When the cover 21 is in the first orientation, the opening portion 241 is connected to the buckling protrusion 13 (FIG. 8C).

With reference to FIGS. 1B, 8A, 8B and 8C, in one embodiment, the elastic sheet 24 comprises an inclined surface 242. The buckling protrusion 13 comprises a curved surface 131. While the cover 21 is being rotated from second orientation to the first orientation, the curved surface 131 pushes the inclined surface 242 to deform the elastic sheet 24, and the inclined surface 242 is moved along the curved surface 131. Finally, the elastic sheet 24 connects the buckling protrusion 13 (as shown in FIG. 8C), and the elastic sheet 24 returns to the original state without being curved.

FIG. 8D shows the elastic sheet separated from the housing buckling portion of the embodiment of the invention. With reference to FIGS. 1A, 8C and 8D, in one embodiment, the elastic sheet 24 further comprises a holding portion 243. The user can separate the elastic sheet 24 from the housing buckling portion 13 by pressing the holding portion 243, and the elastic sheet 24 is thus deformed. The restriction of the housing buckling portion 13 to the cover 21 is removed, and the cover 21 can be rotated from the first orientation to the second orientation.

Utilizing the case and the restriction mechanism of the embodiment of the invention, the user can easily maintain or replace the electronic elements (for example, hard disks or display modules) after raising the cover. In particular, when the cover is raised, the restriction unit restricts the rotation of the cover. The cover is prevented from unexpected falling when the user replaces the electronic elements, and the operation safety of the user is improved.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A case, comprising:
a housing;
a cover, pivoting on the housing, wherein the cover selectively rotates relatively to the housing; and
a restriction unit, connected to the cover and moveably connected to the housing, wherein an orientation of the cover is restricted by the restriction unit selectively.

2. The case as claimed in claim 1, further comprising a linkage, wherein the housing has a receiving portion, the cover selectively rotates between a first orientation and a second orientation relatively to the housing, a first end of the linkage pivots on the cover, a second end of the linkage connects to the restriction unit, and the movement of the linkage is restricted by the restriction unit selectively.

3. The case as claimed in claim 2, wherein the restriction unit comprises a slider, the slider is connected to the housing, and selectively be moved between a first slider position and a second slider position relatively to the housing, the second end of the linkage pivots on the slider, when the cover is in the first orientation, the slider is in the first slider position, and when the cover is in the second orientation, the slider is in the second slider position.

4. The case as claimed in claim 3, wherein the slider comprises a slider wedging portion, the housing comprises a housing wedging portion, when the slider is in the second slider position, the slider wedging portion is wedged against the housing wedging portion.

5. The case as claimed in claim 4, wherein the slider comprises an elastic arm, the slider wedging portion is formed on a free end of the elastic arm, the housing wedging portion comprises a slot, when the slider is in the second slider position, the slider wedging portion is wedged against an inner wall of the slot.

6. The case as claimed in claim 5, wherein the slider comprises a protrusion, the protrusion is formed on the elastic arm, and the protrusion corresponds to the slot.

7. The case as claimed in claim 4, wherein the slider comprises a guiding groove, the housing comprises a guiding post, and the guiding post slides along the guiding groove.

8. The case as claimed in claim 4, wherein the cover comprises a cover pivoting portion, the cover pivots on the housing via the cover pivoting portion, and when the cover is in the second orientation, the first end of the linkage, the second end of the linkage and the cover pivoting portion are not collinear.

9. The case as claimed in claim 3, further comprising a stopper, wherein the stopper is adjustably connected to the housing, the slider comprises a slider wedging portion, and when the slider is in the second slider position, the slider wedging portion is wedged against the stopper.

10. The case as claimed in claim 9 wherein the slider comprises an elastic arm, the slider wedging portion is formed on the free end of the elastic arm, the housing comprises a slot, the stopper comprises a stopper wedging portion, and the stopper wedging portion is wedged against the slot.

11. The case as claimed in claim 10, wherein the housing comprises a positioning post, the stopper comprises a plurality of elastic wedging portions, and the positioning post is selectively connected with one of the elastic wedging portions.

12. The case as claimed in claim 2, wherein the housing comprises a first slot, the second end of the linkage slides along the first slot, when the cover is in the first orientation, the second end of the linkage is in a first position of the first slot, when the cover is in the second orientation, the second end of the linkage is in a second position of the first slot, the second end of the linkage is restricted by the restriction unit selectively, the restriction unit comprises a block and a spring, the spring is connected to the block and the housing, and when the second end of the linkage is in the second position of the first slot, the block restricts the second end of the linkage.

13. The case as claimed in claim 12, wherein the housing comprises a second slot, the block slides along the second slot, and an extending direction of the first slot is perpendicular to an extending direction of the second slot.

14. The case as claimed in claim 2, wherein the cover further comprises an elastic sheet, the housing comprises a housing buckling portion, when the cover is in the first orientation, the elastic sheet is connected to the housing buckling portion, the elastic sheet comprises an opening portion, the housing buckling portion comprises a buckling protrusion, when the cover is in the first orientation, the opening portion is connected to the buckling protrusion.

15. The case as claimed in claim 14, wherein the elastic sheet comprises an inclined surface, the buckling protrusion comprises a curved surface, when the cover is rotated from the second orientation to the first orientation, the inclined surface is pushed by the curved surface, the elastic sheet is deformed, and the inclined surface is moved along the curved surface.

16. A restriction mechanism, connected to a housing and a cover, the cover pivoting on the housing, comprising:
a linkage, connected to the cover and the housing; and
a restriction unit, connected to the linkage, wherein the cover is moved with the linkage for being rotated relatively to the housing, and the restriction unit is moved relatively to the housing via the linkage.

17. The restriction mechanism as claimed in claim 16, wherein the restriction unit comprises a slider, the slider is connected to the housing, and the slider selectively moves between a first slider position and a second slider position relatively to the housing, the second end of the linkage pivots on the slider.

18. The restriction mechanism as claimed in claim 17, wherein the slider comprises a slider wedging portion, the housing comprises a housing wedging portion, when the slider is in the second slider position, the slider wedging portion is wedged against the housing wedging portion.

19. The restriction mechanism as claimed in claim 18, wherein the slider comprises an elastic arm, the slider wedging portion is formed on the free end of the elastic arm, the housing wedging portion comprises a slot, when the slider is in the second slider position, the slider wedging portion is wedged against the inner wall of the slot.

20. The restriction mechanism as claimed in claim 17, further comprising a stopper, wherein the stopper is adjustably connected to the housing, the slider comprises a slider wedging portion, when the slider is in the second slider position, the slider wedging portion is wedged against the stopper.
